(19) United States
(12) Patent Application Publication
(10) Pub. No.: US 2016/0252582 A1
(43) Pub. Date: Sep. 1, 2016

(54) STATE-OF-CHARGE ESTIMATING DEVICE, STATE-OF-CHARGE DETERMINING METHOD, AND STATE-OF-CHARGE DETERMINING PROGRAM

(71) Applicant: Panasonic Intellectual Property Management Co., Ltd., Osaka (JP)

(72) Inventors: TAKUMA IIDA, Kanagawa (JP); HIROYUKI JINBO, Kanagawa (JP)

(21) Appl. No.: 15/150,270

(22) Filed: May 9, 2016

Related U.S. Application Data
(63) Continuation of application No. PCT/JP2014/006017, filed on Dec. 2, 2014.

(30) Foreign Application Priority Data
Dec. 5, 2013 (JP) 2013-252088

(51) Int. Cl. G01R 31/36; H01M 10/06; H01M 10/42

(52) U.S. Cl. CPC G01R 31/3637; H01M 10/4285; H01M 10/06; G01R 31/3651; G01R 31/3679

(57) ABSTRACT

A state-of-charge estimating device includes an open-circuit voltage estimating part, a map selecting part, and a state-of-charge estimating part. The open-circuit voltage estimating part estimates an open-circuit voltage of a secondary battery. The map selecting part selects a map indicating a relationship between a first open-circuit voltage and a state of charge of the secondary battery, based on the first open-circuit voltage of the secondary battery fully charged. The state-of-charge estimating part estimates the state of charge corresponding to a second open-circuit voltage after estimating the first open-circuit voltage, based on the selected map.

### TECHNICAL FIELD

The present disclosure relates to a state-of-charge estimating device that determines a state of charge of a secondary battery, a state-of-charge determining method, and a state-of-charge determining program.

### BACKGROUND ART

A known typical state-of-charge (SOC) estimating method involves acquiring an open-circuit voltage (OCV) of a battery and estimating a SOC of the battery in accordance with an OCV-SOC map indicating a relationship between the OCV and SOC of the battery (for example, Patent Literature 1).

Patent Literature 1 discloses a state-of-charge estimating device that causes an electronic control unit (ECU) to store a plurality of maps each indicating a relationship between a battery voltage V and a SOC. Each of the maps is prepared in connection with a battery temperature T and a battery degradation state. The state-of-charge estimating device selects one from the plurality of maps, based on a battery temperature T and a battery degradation state of a battery, and then determines a SOC of the battery, using the selected map.

### CITATION LIST

Patent Literature

PTL 1: Japanese Laid-Open Patent Publication No. 2002-286818

### SUMMARY OF THE INVENTION

One non-limiting and explanatory embodiment of the present disclosure provides a state-of-charge estimating device that accurately estimates a SOC, a state-of-charge determining method, and a state-of-charge determining program.

A state-of-charge estimating device according to one aspect of the present disclosure includes an open-circuit voltage estimating part, a map selecting part, and a state-of-charge estimating part. The open-circuit voltage estimating part estimates an open-circuit voltage of a secondary battery. The map selecting part selects a map indicating a relationship between a first open-circuit voltage and a state of charge of the secondary battery, based on the first open-circuit voltage of the secondary battery fully charged. The state-of-charge estimating part estimates the state of charge corresponding to a second open-circuit voltage after estimating the first open-circuit voltage, based on the selected map.

A state-of-charge estimating method according to another aspect of the present disclosure includes a step of estimating an open-circuit voltage of a secondary battery. The state-of-charge estimating method also includes a step of selecting a map indicating a relationship between a first open-circuit voltage and a state of charge of the secondary battery, based on the first open-circuit voltage of the secondary battery fully charged. The state-of-charge estimating method also includes a step of estimating the state of charge corresponding to a second open-circuit voltage after estimating the first open-circuit voltage, based on the selected map.

A state-of-charge determining program according to still another aspect of the present disclosure causes a computer to execute the state-of-charge estimating method.

According to the present disclosure, it is possible to accurately estimate a SOC by preparing a relationship between an open-circuit voltage and a SOC of a secondary battery in accordance with a factor of degradation of the secondary battery, and by estimating the SOC.

### BRIEF DESCRIPTION OF DRAWINGS

FIG. 1 is a block diagram illustrating a configuration of a state-of-charge estimating device according to an exemplary embodiment of the present disclosure.

FIG. 2 is a graph illustrating a current-voltage relationship for a lead-acid battery.

FIG. 3 is a graph illustrating an OCV-SOC characteristic of an initial battery and OCV-SOC characteristics of batteries which are different in number of charge and discharge cycles from each other.

FIG. 4 is a graph illustrating an OCV-SOC characteristic of an initial battery and an OCV-SOC characteristic of a sulfated battery.

FIG. 5 is a flowchart illustrating a processing procedure to be executed by the state-of-charge estimating device.

### DESCRIPTION OF EMBODIMENT

Prior to a description of an exemplary embodiment of the present disclosure, a description will be given of a requirement for conventional state-of-charge estimating devices. The state-of-charge estimating device disclosed in Patent Literature 1 determines a state of degradation, that is, a degree of degradation of a battery, based on the internal resistance of the battery. However, the relationship between the battery voltage V and the SOC varies due to factors such as grid corrosion, dry-out, and sulfation. The state-of-charge estimating device in Patent Literature 1 gives no consideration to the factors of degradation of a battery and therefore fails to accurately estimate a SOC.

An exemplary embodiment of the present disclosure will be described in detail with reference to the accompanying drawings.

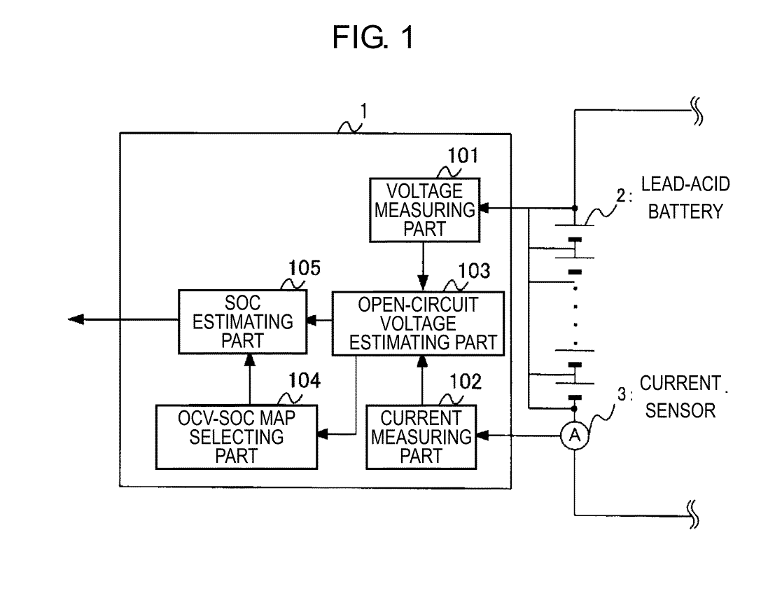

FIG. 1 is a block diagram illustrating a configuration of state-of-charge estimating device 1 according to an exemplary embodiment of the present disclosure. With reference to FIG. 1, a description will be given of the configuration of state-of-charge estimating device 1.

Lead-acid battery 2 includes an almost prismatic casing serving as a battery container. The casing accommodates a group of electrode plates. The casing is made of, for example, a polymeric resin such as polyethylene (PE). The group of electrode plates includes a plurality of negative electrode plates and a plurality of positive electrode plates laminated alternately via separators. The casing has an upper opening, and an upper portion of the casing is bonded or welded to a lid made of a polymeric resin such as PE. Thus, the casing is hermetically sealed with the lid. The lid has a rod-like positive electrode terminal and a rod-like negative electrode terminal each disposed thereon in an upright position to supply power from lead-acid battery 2 serving as a power source to the outside.

Voltage measuring part 101 includes, for example, a differential amplifier and measures a voltage of liquid type lead-acid battery 2. Current measuring part 102 measures a current flowing through lead-acid battery 2, in cooperation with current sensor 3 such as a Hall element.

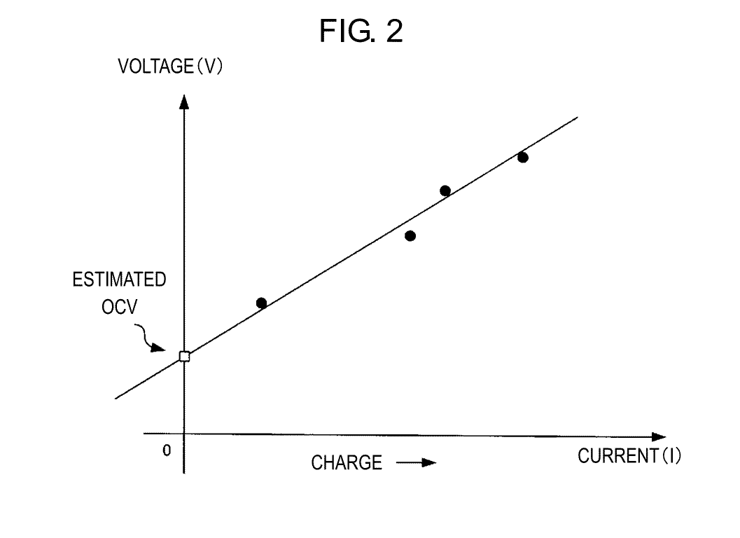

Open-circuit voltage estimating part 103 estimates an open-circuit voltage (OCV) of lead-acid battery 2 in a fully charged condition, based on the result of measurement by voltage measuring part 101 and the result of measurement by current measuring part 102. Open-circuit voltage estimating part 103 outputs the estimated OCV in the fully charged condition to OCV-SOC map selecting part (hereinafter, simply referred to as map selecting part) 104. The fully charged condition does not necessarily refer to a SOC of 100%. For example, the fully charged condition may refer to a SOC ranging from 90% to 100%. Further, open-circuit voltage estimating part 103 also estimates the OCV, based on the result of measurement by voltage measuring part 101 and the result of measurement by current measuring part 102. Open-circuit voltage estimating part 103 outputs the estimated OCV to state-of-charge estimating part (hereinafter, simply referred to as SOC estimating part) 105. As illustrated in FIG. 2, open-circuit voltage estimating part 103 may define, as the estimated OCV, an intercept (white rectangle) of a linear function obtained by, for example, the least square method based on plural sets of measured values VM and IM. With regard to a linear approximation, preferably, the OCV is estimated using at least three sets of voltage and current in order to improve the estimation accuracy. Since the OCV becomes stable when about 1 to 3 hours elapse after stopping discharge or charge including full charge, open-circuit voltage estimating part 103 may measure this OCV as the estimation of OCV.

Map selecting part 104 stores a plurality of OCV-SOC maps prepared in accordance with different OCVs of lead-acid battery 2 in the fully charged condition. Map selecting part 104 selects the OCV-SOC map corresponding to the OCV in the fully charged condition output from open-circuit voltage estimating part 103. Map selecting part 104 outputs the selected OCV-SOC map to SOC estimating part 105. A specific description of the OCV-SOC maps will be given later.

SOC estimating part 105 estimates a SOC corresponding to the OCV output from open-circuit voltage estimating part 103, using the OCV-SOC map output from map selecting part 104.

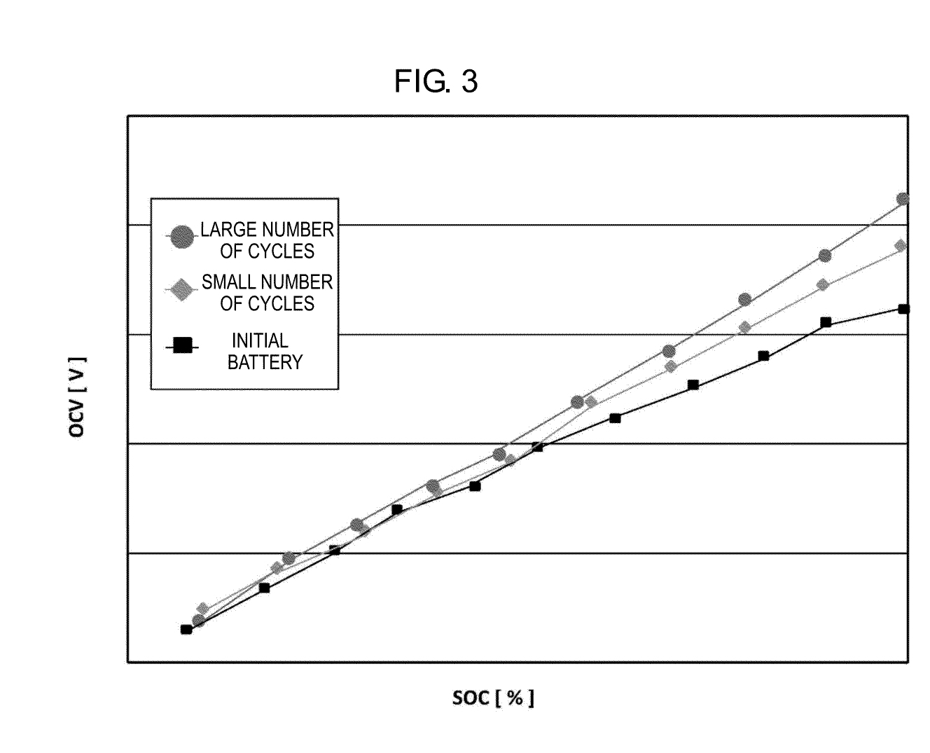

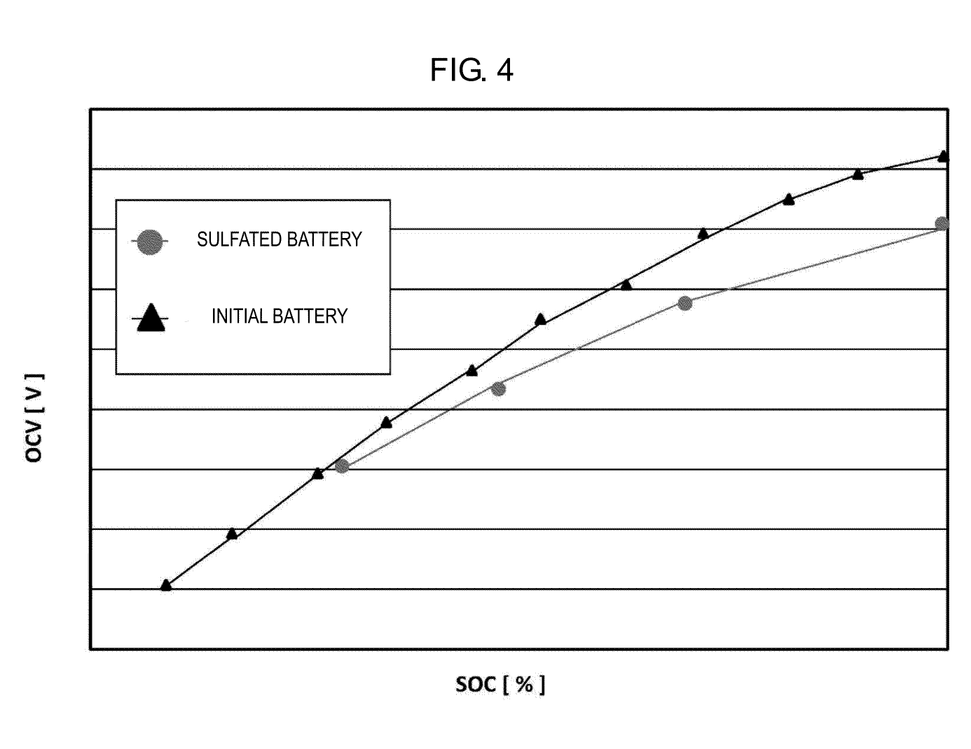

Next, a description will be given of the OCV-SOC maps stored in map selecting part 104. FIG. 3 illustrates an OCV-SOC characteristic of an initial battery and OCV-SOC characteristics of batteries which are different in number of charge and discharge cycles from each other. FIG. 4 illustrates an OCV-SOC characteristic of an initial battery and an OCV-SOC characteristic of a sulfated battery. In FIGS. 3 and 4, the horizontal axis indicates a SOC and the vertical axis indicates an OCV. Herein, the initial battery refers to a battery of which the number of charge and discharge cycles is 0. The initial battery in FIG. 3 is identical in characteristic to the initial battery in FIG. 4.

As is apparent from FIG. 3, the initial battery and the batteries, which are different in number of charge and discharge cycles from one another, are different in OCV value from one another in the case where each battery has the SOC value on the far-right portion of FIG. 3, that is, in the case where each battery is fully charged (SOC: about 90-100%). FIG. 3 illustrates the case of the small number of charge and discharge cycles (at most several tens to several hundreds of cycles) and the case of the large number of charge and discharge cycles (more than several hundreds of cycles, e.g., about 1000 cycles). It is apparent from FIG. 3 that the number of charge and discharge cycles exerts an influence on the degree of grid corrosion or dry-out.

As is apparent from FIG. 4, the initial battery and the sulfated battery are different in OCV value from each other in the case where each battery has the SOC value on the far-right portion of FIG. 4, that is, in the case where each battery is fully charged (SOC: about 90-100%).

As described above, map selecting part 104 is capable of determining the factor of degradation of lead-acid battery 2 from the OCV in the fully charged condition. Therefore, map selecting part 104 prepares the plurality of OCV-SOC maps in accordance with the respective factors of degradation and selects one from the OCV-SOC maps in accordance with the determined factor of degradation.

As is apparent from the characteristics illustrated in FIGS. 3 and 4, the battery which undergoes at least one of corrosion and dry-out is higher in OCV in the fully charged condition than the initial battery whereas the sulfated battery is lower in OCV in the fully charged condition than the initial battery. Therefore, map selecting part 104 may determine the factor of degradation from a comparison between the OCV in the last fully charged condition and the OCV in the present fully charged condition. More specifically, if the OCV in the present fully charged condition is higher than the OCV in the last fully charged condition, map selecting part 104 determines that the battery undergoes at least one of corrosion and dry-out. On the other hand, if the OCV in the present fully charged condition is lower than the OCV in the last fully charged condition, map selecting part 104 determines that the battery is sulfated. Map selecting part 104 may select one from the OCV-SOC maps in accordance with the result of determination.

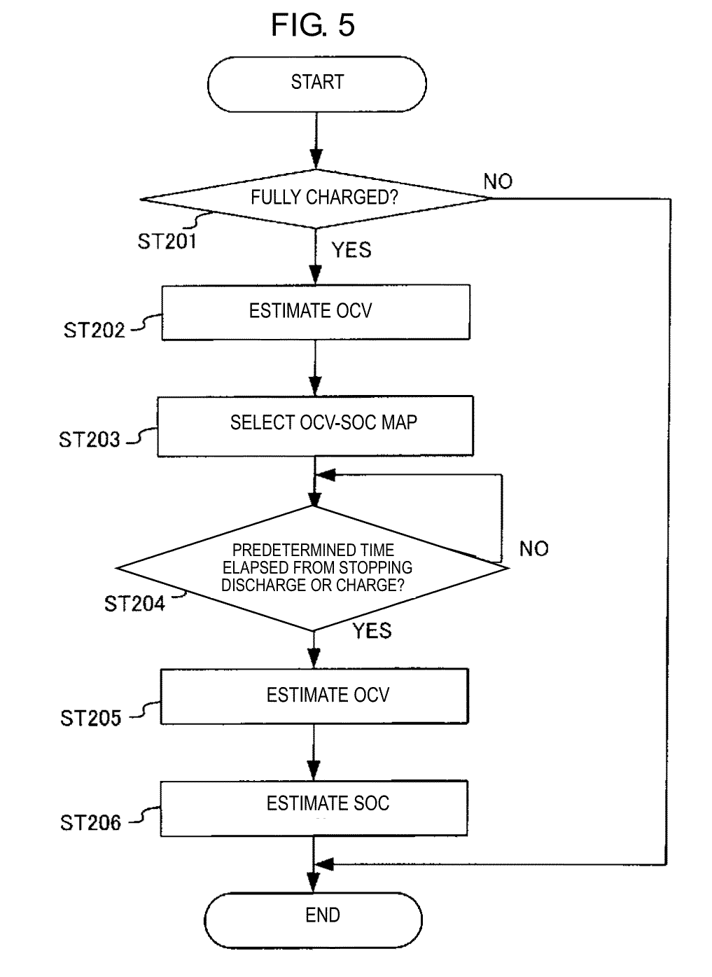

FIG. 5 is a flowchart illustrating a processing procedure to be executed by state-of-charge estimating device 1. With reference to FIG. 5, next, a description will be given of the processing procedure to be executed by state-of-charge estimating device 1.

Open-circuit voltage estimating part 103 determines whether lead-acid battery 2 is fully charged (ST201). If lead-acid battery 2 is fully charged (ST201: YES), oₚen-circuit voltage estimating part 103 estimates the OCV in the fully charged condition (ST202). If lead-acid battery 2 is not fully charged (ST201: NO), state-of-charge estimating device 1 ends the processing.

Map selecting part 104 selects the OCV-SOC map corresponding to the OCV in the fully charged condition estimated in step ST202 (ST203). Open-circuit voltage estimating part 103 determines whether a predetermined time is elapsed from stopping discharge or charge (ST204). If the predetermined time is elapsed from stopping discharge or charge (ST204: YES), the processing proceeds to step ST205. If the predetermined time is not elapsed yet from stopping discharge or charge (ST204: NO), open-circuit voltage estimating part 103 repeats the determination in step ST204 until the predetermined time elapses. The predetermined time is desirably about 1 to 3 hours since an unstable OCV at stopping discharge or charge becomes stable after a lapse of about 1 to 3 hours.

Open-circuit voltage estimating part 103 estimates or measures the OCV after the lapse of the predetermined time from stopping discharge or charge, after estimating the OCV of the full charge (ST205). SOC estimating part 105 estimates the SOC corresponding to the OCV estimated in step ST205, using the OCV-SOC map selected in step ST203 (ST206).

As described above, the state-of-charge estimating device according to the exemplary embodiment stores the plurality of OCV-SOC maps corresponding to the different OCVs of the fully charged lead-acid battery, selects the OCV-SOC map corresponding to the OCV in the fully charged condition, and estimates the SOC corresponding to the OCV. Thus, the state-of-charge estimating device is capable of accurately estimating the SOC, using the OCV-SOC map corresponding to the factor of degradation of the battery.

In the foregoing exemplary embodiment, the method of charging the lead-acid battery is not explicitly described. For example, a constant current-constant voltage (CCCV) method may be employed to determine as full charge a case where a predetermined current value or less continues for a predetermined time. Alternatively, an n-step constant current method of lowering a charge current value by “n” steps in a stepwise manner (see, for example, Japanese Laid-Open Patent Publication No. 2010-160955) may be employed to determine as full charge a point in time when the charge current value is lowered by the “n” steps. In addition, any other methods may be employed. For example, a method of calculating a charge accumulated in a lead-acid battery by current integration may be employed to determine as full charge a case where the charge is accumulated in a predetermined amount.

The lead-acid battery and the state-of-charge estimating device described in the foregoing exemplary embodiment are mountable in, for example, an electric vehicle, a solar power generation system, an uninterruptible power supply (UPS), a wind power generation system, a fuel cell cogeneration system, and a base station for communications.

The processing executed by the state-of-charge estimating device described in the foregoing exemplary embodiment may be implemented by cloud computing with necessary information offered as appropriate.

The state-of-charge estimating device, the state-of-charge determining method, and the state-of-charge determining program according to the present disclosure are applicable to, for example, an electric charger and a vehicle control unit (VCU).

1. A state-of-charge estimating device comprising:
an open-circuit voltage estimating part that estimates an open-circuit voltage of a secondary battery;
a map selecting part that selects a map indicating a relationship between a first open-circuit voltage and a state of charge of the secondary battery, based on the first open-circuit voltage of the secondary battery fully charged; and
a state-of-charge estimating part that estimates the state of charge corresponding to a second open-circuit voltage after estimating the first open-circuit voltage, based on the selected map.

2. The state-of-charge estimating device according to claim 1, wherein
the map selecting part estimates a factor of degradation of the secondary battery, based on the first open-circuit voltage.

3. The state-of-charge estimating device according to claim 2, wherein
the secondary battery is a lead-acid battery, and
the factor of degradation includes dry-out or grid corrosion, and sulfation.

4. The state-of-charge estimating device according to claim 1, wherein
the state-of-charge calculating part calculates the state-of-charge after a lapse of a predetermined time from stopping of charge or discharge of the secondary battery.

5. The state-of-charge estimating device according to claim 1, wherein
the state-of-charge estimating device is mounted in an electric vehicle.

6. A state-of-charge determining method comprising the steps of:
estimating an open-circuit voltage of a secondary battery;
selecting a map indicating a relationship between a first open-circuit voltage and a state of charge of the secondary battery, based on the first open-circuit voltage of the secondary battery fully charged; and
estimating the state of charge corresponding to a second open-circuit voltage after estimating the first open-circuit voltage, based on the selected map.

7. A state-of-charge determining program that causes a computer to execute the steps of:
estimating an open-circuit voltage of a secondary battery;
selecting a map indicating a relationship between a first open-circuit voltage and a state of charge of the secondary battery, based on the first open-circuit voltage of the secondary battery fully charged; and
estimating the state of charge corresponding to a second open-circuit voltage after estimating the first open-circuit voltage, based on the selected map.
